(19) United States
(12) Patent Application Publication
(10) Pub. No.: US 2010/0144157 A1
(43) Pub. Date: Jun. 10, 2010

(54) PLASMA ETCHING APPARATUS AND METHOD

(75) Inventors: Michiko NAKAYA, Nirasaki-shi (JP); Koji MARUYAMA, Nirasaki-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, Tokyo (JP)

(21) Appl. No.: 12/709,035

(22) Filed: Feb. 19, 2010

Related U.S. Application Data
(62) Division of application No. 11/678,833, filed on Feb. 26, 2007.
(60) Provisional application No. 60/779,969, filed on Mar. 8, 2006.

(30) Foreign Application Priority Data
Feb. 27, 2006 (JP) 2006-049639

(51) Int. Cl. H01L 21/3065

(52) U.S. Cl. 438/710; 257/E21.218

(57) ABSTRACT

A plasma etching apparatus includes an evacuable processing chamber for performing a plasma etching process on a target object; a mounting table for mounting thereon the target object in the processing chamber; and a shower head facing the mounting table, for introducing a processing gas for generating a plasma to the processing chamber. Further, the apparatus includes a ring-shaped protrusion protruded from a bottom surface of the shower head toward the mounting table; and a plurality of gas introducing openings inclusively arranged in an area smaller than the target object in an inner central portion of the ring-shaped protrusion on the bottom surface of the shower head.

### CROSS-REFERENCE TO RELATED APPLICATIONS

This application is a divisional of U.S. Application Ser. No. 11/678,833, filed on Feb. 26, 2007, the entire content of which is incorporated herein by reference, and claims priority under 35 U.S.C. 119 to Japanese Patent Application No. 2006-049639, filed on Feb. 27, 2006, and U.S. Provisional Application No. 60/779,969 filed on Mar. 8, 2006.

### FIELD OF THE INVENTION

The present invention relates to a plasma etching apparatus and method; and, more particularly, to a plasma etching apparatus and method for use in etching a target object by using a plasma.

### BACKGROUND OF THE INVENTION

A manufacturing process of a semiconductor device such as a three-dimensional stack package device or the like includes a silicon etching for forming wiring through holes, mechanical structure grooves or the like.

As for the above silicon etching, there has been generally employed a silicon etching method including the steps of: etching an oxide film such as an SiO₂ film or the like while using a resist formed in a predetermined pattern as a mask; peeling off the resist; and etching silicon while using the SiO₂ film as a mask by using an etching gas containing, e.g., SF₆ and O₂. However, in recent years, there has been examined a method for directly etching silicon by using a resist as a mask to thereby reduce the number of processes.

After the silicon is etched, an etching hole is subjected to an insulation film forming process, a seed metal layer forming process, a Cu plating process and the like for the fabrication of the three-dimensional package device. Accordingly, the etching hole needs to be formed in a taper shape having an inclined sidewall such that a diameter at its bottom edge is smaller than that at its top edge. However, in case silicon is etched when a resist is used as a mask, it is difficult to obtain a uniform etching rate (i.e., a depth of a hole) in a surface of a semiconductor wafer serving as a target substrate and an etching profile is difficult to control. To be specific, the etching rate is higher in a central portion (center) of the semiconductor wafer than in a peripheral portion (edge) thereof. Therefore, a hole formed in the central portion tends to be deeper than that in the peripheral portion, and the hole formed in the peripheral portion tends to have a non-slanted substantially vertical sidewall angle compared with that in the central portion.

Meanwhile, although it is related to an etching of an insulating film, there is proposed a technique capable of performing an etching process while preventing a plasma diffusion by using a downward protrusion provided at a shield ring around an upper electrode to thereby realize a high-speed micro etching (see, e.g., Japanese Patent Laid-open Application No. H8-335568 (For example, see FIG. 2)).

Moreover, there is also suggested a technique for providing a shower head provided with a shutter mechanism having an opening whose diameter can be varied to regulate an injection amount and a flow of gas to be blown-off from the shower head (see, e.g., Japanese Patent Laid-open Application No. H10-60673 (For example, see FIG. 1))

Although the techniques disclosed in Japanese Patent Laid-open Application Nos. H8-335568 and H10-60673 have suggested the protrusion provided at the shield ring and the shutter mechanism of the shower head, they are completely silent on achieving a uniform etching rate or a tapered etching profile in performing a silicon etching using a resist as a mask.

### SUMMARY OF THE INVENTION

It is, therefore, an object of the present invention to ensure intra-surface uniformity of an etching rate and control an etching profile while performing a silicon etching by using a resist as a mask.

In accordance with a first aspect of the invention, there is provided a plasma etching apparatus including: an evacuable processing chamber for performing a plasma etching process on a target object; a mounting table for mounting thereon the target object in the processing chamber; a shower head facing the mounting table, for introducing a processing gas for generating a plasma to the processing chamber; a ring-shaped protrusion protruded from a bottom surface of the shower head toward the mounting table; and a plurality of gas introducing openings inclusively arranged in an area smaller than the target object in an inner central portion of the ring-shaped protrusion on the bottom surface of the shower head.

In accordance with the plasma etching apparatus of the first aspect of the present invention, the ring-shaped protrusion is provided on the bottom surface of the shower head and, also, the gas introducing openings are inclusively arranged in the inner central portion of the ring-shaped protrusion. With the presence of the ring-shaped protrusion, the uniform pressure is obtained in the plasma generation space. Accordingly, it is possible to control the plasma density and the amount of deposits especially in the vicinity of the ring-shaped protrusion. Further, the exclusive arrangement of the gas introducing openings in the central portion increases the gas velocity in the space above the central portion of the target object, which leads to a suppression of the generation of etchants in the central portion. As a result, it is possible to obtain the intra-surface uniformity of the etching rate and control the etching profile.

In accordance with the first aspect of the present invention, it is preferable to form a pair of facing electrodes by using the mounting table as a lower electrode and the shower head as an upper electrode. Preferably, an outer diameter of the ring-shaped protrusion is about 1.1 to about 1.5 times a diameter L of the target object. Further, preferably, an inner diameter of the ring-shaped protrusion is greater than the diameter L of the target object. Accordingly, a plasma generation space is formed in a space above the target object, so that the intra-surface etching uniformity can be ensured.

Preferably, a height of the ring-shaped protrusion is equal to or greater than about 0.4 times a distance from the mounting table to the shower head. Accordingly, the conductance of the gas flow is reduced, so that the uniform pressure is obtained in the space surrounded by the ring-shaped protrusion. Further, preferably, the gas introducing openings are inclusively formed in an area of about 0.3 L×0.3 L to about 0.7 L×0.7 L, L being a diameter of the target object. Therefore, the gas velocity can be sufficiently increased in the space above the central portion of the target substrate.

In accordance with a second aspect of the invention, there is provided a plasma etching method for performing, by using the plasma etching apparatus, a plasma etching process on the target object having an etching target layer mainly made of silicon and a pre-patterned resist layer formed above the etching target layer by applying a plasma generated from a processing gas containing SF₆ and O₂ to the etching target layer while using the resist layer as a mask.

In accordance with the second aspect of the present invention, the etching target layer is a silicon substrate or a silicon layer.

In accordance with a third aspect of the invention, there is provided a computer-executable control program which controls, when executed, the plasma etching apparatus such that the plasma etching method of the second aspect of the invention.

In accordance with a fourth aspect of the invention, there is provided a computer readable storage medium that stores therein a computer-executable control program, wherein the control program controls the plasma etching apparatus such that the plasma etching method of the second aspect of the invention.

The plasma etching apparatus of the present invention has on the bottom surface of the shower head the ring-shaped protrusion protruded toward the mounting table and the multiple gas introducing openings inclusively distributed in an area smaller than the target object. By using such a plasma etching apparatus, it is possible to obtain the uniform etching depth in the surface of the target object and control the etching to be carried out in a tapered shape. Since the plasma etching apparatus can be effectively used for manufacturing high-reliability semiconductor devices, it is possible to cope with a miniaturization and a high integration of the semiconductor devices.

### BRIEF DESCRIPTION OF THE DRAWINGS

The above and other objects and features of the present invention will become apparent from the following description of preferred embodiments, given in conjunction with the accompanying drawings, in which:

FIG. 1 shows a cross sectional view of a magnetron RIE plasma etching apparatus suitable for performing an etching method of the present invention;

FIG. 2 describes a schematic horizontal cross sectional view of a dipole ring magnet unit arranged around an outer periphery of a chamber of the apparatus of FIG. 1;

FIG. 3 provides a schematic diagram to explain an electric field and a magnetic field formed in the chamber;

FIG. 4 presents a diagram to explain an arrangement of a ring-shaped protrusion and gas introducing openings;

FIG. 5 shows a top view of a bottom surface of a shower head to explain the arrangement of the ring-shaped protrusion and the gas introducing openings;

FIG. 6 represents a schematic cross sectional view showing a vicinity of a surface of a semiconductor wafer being plasma etched; and

FIG. 7 illustrates a schematic cross sectional view showing a vicinity of a surface of a plasma etched semiconductor wafer.

### DETAILED DESCRIPTION OF THE EMBODIMENT

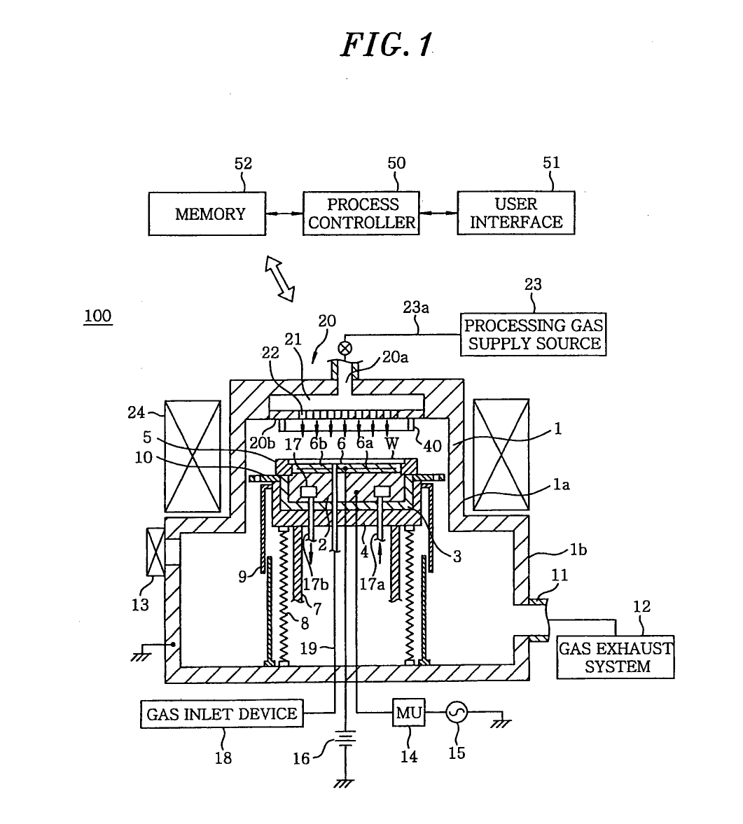

Hereinafter, embodiments of the present invention will be described with reference to the accompanying drawings. FIG. 1 shows a cross sectional view of a magnetron RIE plasma etching apparatus 100 in accordance with a first embodiment of the present invention. The plasma etching apparatus 100 includes a chamber (processing vessel) 1 having a wall made of, for example, aluminum. The chamber 1 is hermetically sealed and is configured to have a stepped cylindrical shape with an upper portion 1a having a smaller diameter and a lower portion 1b having a larger diameter.

Installed in the chamber 1 is a supporting table 2 for horizontally supporting the wafer W, the wafer W being a single crystalline Si substrate functioning as a target object. The supporting table 2 is made of, for example, aluminum and is supported by a conductive support 4 via an insulator 3. Furthermore, a focus ring 5 formed of a material other than Si, for example, quartz, is mounted on the periphery of the top surface of the supporting table 2. The supporting table 2 and the support 4 are configured to move up and down by a ball screw mechanism having ball screws 7. Further, the driving portion thereof located below the support 4 is covered with a stainless steel (SUS) bellows 8, and a bellows cover 9 is installed to enclose the bellows 8. Also, a baffle plate 10 is installed outside the focus ring 5 and the focus ring 5 is electrically connected to the chamber 1 via the baffle plate 10, the support 4 and the bellows 8. The chamber 1 is grounded.

A gas outlet port 11 is formed at the sidewall of the lower portion 1b in the chamber 1, and a gas exhaust system 12 is connected to the gas outlet port 11. By operating a vacuum pump of the gas exhaust system 12, the chamber 1 is depressurized to a specific vacuum level. Further, a gate valve 13 for opening and closing a loading/unloading port for the wafer W is installed at the upper sidewall of the lower portion 1b in the chamber 1.

A first high frequency power supply 15 for plasma generation is connected to the supporting table 2 via a matching unit 14 (MU), and a high frequency power at a specific frequency is applied to the supporting table 2 from the first high frequency power supply 15. Further, an electrically grounded shower head 20 to be described later in detail is disposed above the supporting table 2 while facing the supporting table 2 in parallel. Accordingly, the supporting table 2 and the shower head 20 are configured to function as a pair of electrodes.

An electrostatic chuck 6 for electrostatically attracting and holding the wafer W thereon is provided on the top surface of the supporting table 2. The electrostatic chuck 6 has an electrode 6a embedded in an insulator 6b, and the electrode 6a is connected to a DC power supply 16. By applying a voltage to the electrode 6a from the DC power supply 16, an electrostatic force, e.g. a Coulomb force, is generated, thereby attracting and holding the wafer W.

A coolant path 17 is formed inside the supporting table 2 to continuously introduce a coolant via a coolant introducing line 17a and discharge via a coolant discharge line 17b. By this circulation of the coolant, the cold heat of the coolant is transferred from the supporting table 2 to the wafer W, whereby the processing surface of the wafer W is maintained at a desired temperature level.

Further, a cooling gas is introduced between the top surface of the electrostatic chuck 6 and the rear surface of the wafer W from a gas inlet device 18 via a gas supply line 19 in order to effectively cool the wafer W with the coolant circulated in the coolant path 17 even if the chamber 1 is pumped by the gas exhaust system 12 to be maintained in a vacuum state. By introducing the cooling gas, the cold heat of the coolant is efficiently transferred to the wafer W, thereby improving the cooling efficiency for the wafer W. He can be employed as the cooling gas, for example.

The shower head 20 is provided on a ceiling wall portion of the chamber 1 while facing the supporting table 2. The shower head 20 has a plurality of gas introducing openings 22 at a bottom surface 20b thereof. Installed around the gas introducing openings 22 is a ring-shaped protrusion 40 formed at a cylindrical wall body protruded toward the supporting table 2 facing the gas introducing openings 22. The ring-shaped protrusion 40 may be provided as a unit with the shower head 20 or may be separately attached to the bottom surface of the shower head 20. The ring-shaped protrusion 40 and the shower head 20 are made of a same material, e.g., aluminum or the like. If necessary, as in the shower head 20, an alumite film or a thermally sprayed ceramic coating such as Y₂O₃ or the like may be formed on a surface of the ring-shaped protrusion 40.

The shower head 20 has a gas inlet 20a at an upper portion thereof and a hollow space 21 formed therein. One end of a gas supply line 23a is connected to the gas inlet 20a, and the other end thereof is connected to a processing gas supply system 23 which serves to supply a processing gas containing an etching gas and a dilution gas.

As for the etching gas, it is preferable to use a gas containing SF₆ and O₂. SF₆ gas is suitable for a silicon etching because a density of fluorine atoms generated from a plasma is relatively high (up to several times) compared with other fluorine-based gases and, also, a sulfur atom facilitates the etching by preventing an oxidation on an Si surface. Further, O₂ gas facilitates a vertical anisotropic etching by forming a silicon oxide film (SiO) on a sidewall through a reaction with silicon on a silicon substrate. S₂F₁₀, NF₃, SiF₄ or the like may be used in place of the aforementioned SF₆ gas.

The processing gas is introduced into the space 21 of the shower head 20 from the processing gas supply system 23 via the gas supply line 23a and the gas inlet 20a so as to be discharged through the gas introducing openings 22.

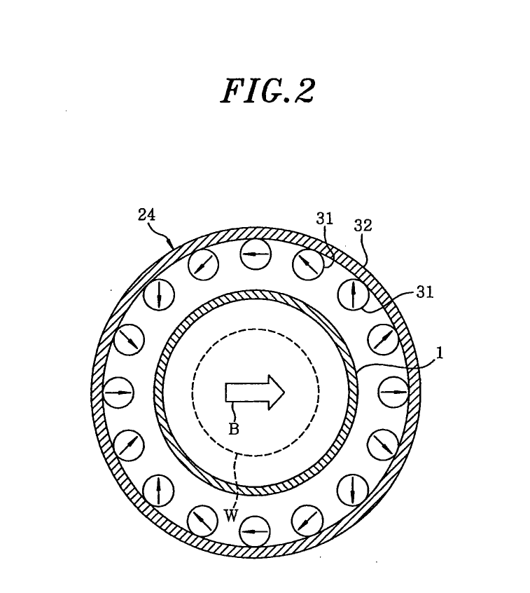

Meanwhile, a dipole ring magnet unit 24 is concentrically disposed around the upper portion 1a of the chamber 1. As illustrated in a horizontal cross sectional view of FIG. 2, the dipole ring magnet 24 is configured such that a plurality of anisotropic segment columnar magnets 31 is attached to a ring-shaped magnetic casing 32. For example, 16 of the anisotropic segment columnar magnets 31 are circumferentially disposed in a ring shape. In FIG. 2, arrows shown in the anisotropic segment columnar magnets 31 indicate magnetization directions. As shown in FIG. 2, by arranging the magnetization directions of the anisotropic segment columnar magnets 31 so that they are slightly shifted, a uniform horizontal magnetic field B is formed as a whole along a single direction.

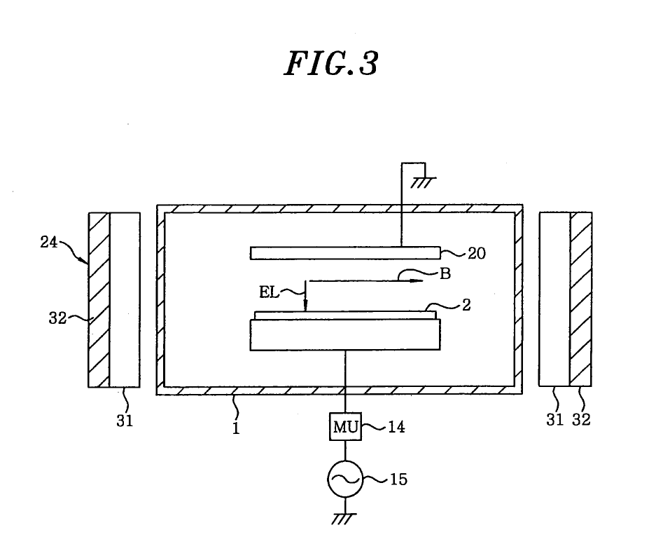

Therefore, as schematically shown in FIG. 3, a vertical electric field EL is formed by the electric power supply 15 and a horizontal magnetic field B is formed by the dipole ring magnet 24 in a space between the supporting table 2 and the shower head 20, which results in a formation of an orthogonal electromagnetic field. In this manner, a magnetron discharge occurs by the orthogonal electromagnetic field thus formed. Accordingly, a high-energy plasma of an etching gas is produced, which is for etching the wafer W.

Each component of the plasma etching apparatus 100 is coupled to and controlled by a process controller 50 having a CPU. A user interface 51 is connected to the process controller 50, wherein the user interface 51 includes, e.g., a keyboard for a process manager to input a command to operate the plasma etching apparatus 100, a display for showing an operational status of the plasma etching apparatus 100, and the like.

Moreover, connected to the process controller 50 is a memory 52 for storing therein, e.g., control programs and recipes including processing condition data and the like to be used in realizing various processes, which are performed in the plasma etching apparatus 100 under the control of the process controller 50.

When a command is received from the user interface 51, the process controller 50 retrieves a necessary recipe from the memory 52 as required to execute the command to perform a desired process in the plasma processing apparatus 100 under the control of the process controller 50. The necessary recipe can be retrieved from a computer-readable storage medium such as a CD-ROM, a hard disk, a flash memory, a flexible disk or the like, or can be transmitted from another apparatus via, e.g., a dedicated line, if necessary.

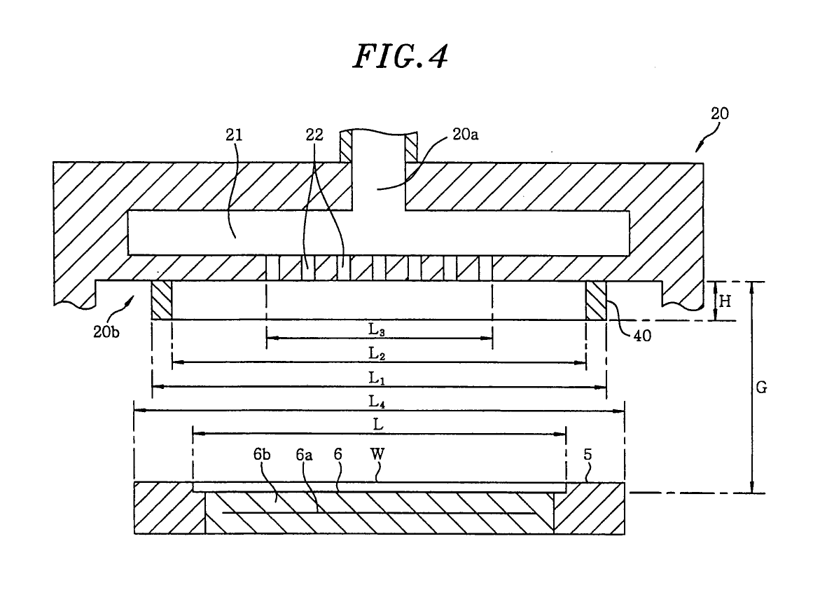

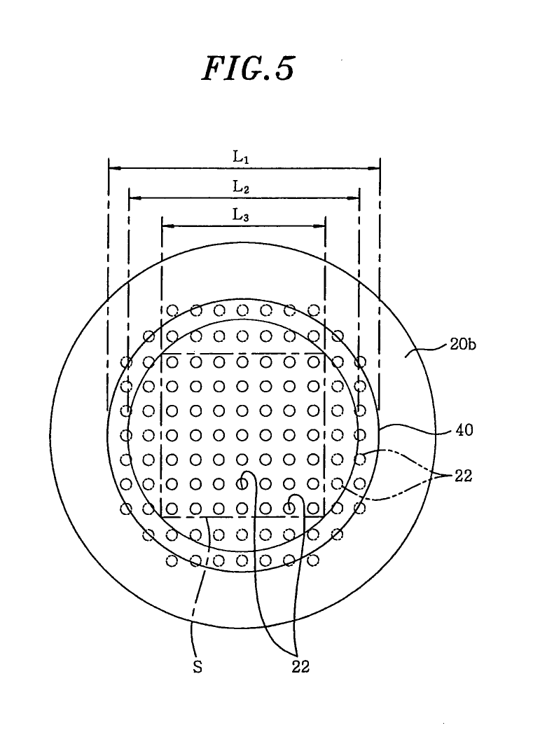

Hereinafter, an arrangement of the ring-shaped protrusion 40 and the gas introducing openings 22 in the shower head 20 will be described with reference to FIGS. 4 and 5. Since the presence of the ring-shaped protrusion 40 on a bottom surface of the shower head 20 decreases a conductance of a flow of the gas discharged through the gas introducing openings 22 of the shower head 20, a uniform pressure distribution can be obtained in a space surrounded by the ring-shaped protrusion 40. Accordingly, the plasma density and the amount of silicon reaction products, which serve as source materials of deposits, are controlled especially in the vicinity of the protrusion in the space surrounded by the ring-shaped protrusion 40. As a result, the amount of a sidewall protective film in the etching hole is regulated, thereby enabling the silicon etching to be performed in an appropriately tapered shape, in which the width at the opening of the etching hole is greater than that at the bottom thereof.

It is preferable that a protruding amount H (height) of the ring-shaped protrusion 40 is greater than or approximately equal to 0.4 times (e.g., about 0.4 times to about 0.8 times) a distance (gap) G between the upper and the lower electrode, i.e., a distance from the bottom surface 20b of the shower head 20 to the top surface of the supporting table 2. If the protruding amount H of the ring-shaped protrusion 40 is less than about 0.4 times the gap G, the conductance of the gas flow is not sufficiently reduced to obtain a uniform pressure in the space surrounded by the ring-shaped protrusion 40. On the other hand, if the protruding amount H is greater than about 0.8 times the gap G, an abrupt decrease in the conductance of the gas flow occurs, which leads to an excessive dissociation of the etching gas components. This excessive dissociation may deteriorate etching characteristics. In addition, the gap G is preferably set in a range of about 25 mm to about 50 mm.

Further, it is preferable that an outer diameter L₁ of the ring-shaped protrusion 40 be greater than about 1 to 1.5 times a diameter L of the wafer W so as to decrease the conductance of the gas flow above the wafer W. Furthermore, it is preferable that the outer diameter L₁ be set smaller than a diameter of a horizontal mounting surface for mounting thereon the wafer W. When the focus ring 5 is provided on the supporting table 2, it is preferred that the outer diameter L₁ of the ring-shaped protrusion 40 be set smaller than an outer diameter L₄ of the focus ring 5.

Meanwhile, an inner diameter L₂ of the ring-shaped protrusion 40 may be set to be greater than the diameter L of the wafer W so as to uniformly form a plasma generation space above the wafer W.

In this embodiment, the gas introducing openings 22 are inclusively provided near the central portion of the bottom surface 20b of the shower head 20, as shown in FIG. 5. To be specific, the gas introducing openings 22 are inclusively distributed in a rectangular area S (L₃×L₃) on the bottom surface 20b of the shower head 20, the area S having a side length L₃ of about 0.3 times to about 0.7 times greater than the diameter L of the wafer W. However, the gas introducing openings 22 are not arranged in an area corresponding to the peripheral portion of the wafer W on the bottom surface 20b of the shower head 20. Further, the gas introducing openings 22 of this embodiment are inclusively provided near the central portion of the bottom surface 20b of the shower head 20 so that all of the gas introducing openings 22 are disposed in the area S smaller than the wafer W. For reference, dotted lines of FIG. 5 depict the gas introducing openings 22 formed outside the area S in the shower head 22 having a conventional arrangement of the gas introducing openings 22.

By inclusively arranging the gas introducing openings 22 in the central portion of the shower head 20, a gas flow rate can be increased in a space above the central portion of the wafer W. The increase of the gas velocity in the space above the central portion of the wafer W decreases a residence time of radicals. As a result, the silicon etching rate at the central portion of the wafer W deteriorates and the intra-surface uniformity of the wafer W is further improved.

Here, in case the shower head 20 includes gas introducing openings 22 in areas other than the central portion thereof, the distribution of the gas introducing openings 22 in the shower head 20 can be controlled by way of sealing the gas introducing openings 22 in the area corresponding to the peripheral portion of the wafer W with insertable members. For example, the gas introducing openings 22 can be inclusively disposed at the central portion of the shower head 20 by controlling the arrangement (distribution area) of the gas introducing openings 22 by way of sealing the gas introducing openings 22 indicated by the dotted lines in FIG. 5.

The following is an explanation of an etching method of the present invention for performing a plasma etching on a silicon (a single crystalline silicon substrate or a polysilicon layer) by using the plasma etching apparatus as configured above. First, the gate valve 13 is opened, and a wafer W is loaded into the chamber 1 to be mounted on the supporting table 2. Next, the supporting table 2 is elevated to a position illustrated in FIG. 1 and, then, an inside of the chamber 1 is exhausted through the gas outlet port 11 by a vacuum pump of the gas exhaust system 12.

A processing gas containing an etching gas and a dilution gas is supplied into the chamber 1 from the processing gas supply system 23 at a specific flow rate. Then, while maintaining the internal pressure of the chamber 1 at a specific pressure level, a specific high frequency power from the high frequency power supply 15 is supplied to the supporting table 2. At this time, the wafer W is attracted and held by, e.g., a Coulomb force generated by a specific voltage applied to the electrode 6a of the electrostatic chuck 6 from the DC power supply 16, and a high frequency electric field is formed between the shower head 20 serving as an upper electrode and the supporting table 2 serving as a lower electrode.

Since the horizontal magnetic field B has been formed by the dipole ring magnet unit 24 between the shower head 20 and the supporting table 2, the orthogonal electromagnetic field is formed in the processing space between the electrodes where the wafer W is present, and a magnetron discharge is generated due to an electron drift produced by the orthogonal electromagnetic field. Moreover, the wafer W is etched by a plasma of the etching gas, the plasma being produced by the magnetron discharge. The pressure increase in the inner space of the ring-shaped protrusion 40 and the gas velocity increase caused by the exclusive arrangement of the gas introducing openings 22 in the central portion lead to improvements in the in-wafer uniformity of the etching rate and the controllability of the etching profile.

In order to improve the etching profile, it is effective to control a temperature of the wafer W. Accordingly, a coolant is circulated in a coolant chamber 17, so that cold heat is transferred to the wafer W via the supporting table 2. As a result, a processing surface of the wafer W can be controlled at a desired temperature.

A frequency and an output of the plasma generating high frequency power supply 15 are appropriately set to generate a desired plasma. When performing the silicon etching, the frequency is preferably about 40 MHz or higher to increase the plasma density directly above the wafer W.

To increase the plasma density right above the wafer W, the dipole ring magnet 24 forms the magnetic field in the processing space between the supporting table 2 and the shower head 20 as the facing electrodes. However, to achieve the effect of the plasma density increase, the magnet preferably has an intensity capable of forming a magnetic field of about 10000 μT (100 G) or higher in the processing space. Although the plasma density may be increased as the magnetic field becomes stronger, for safety precaution it is preferable to set the magnetic field at about 100000 μT (1 kG) or less for safety.

The following is a description on desirable conditions of the silicon etching using the plasma etching apparatus 100. As for an etching gas, it is preferable to mix SF₆ and O₂, at a flow rate of about 100 mL/min (sccm) to about 1000 mL/min(sccm) and at a flow rate of about 0 mL/min (sccm) to about 500 mL/min (sccm), respectively. In order to control an etching profile, a flow rate ratio thereof is preferably between about 3:1 and about 2:1.

A processing pressure preferably ranges from about 10 Pa to about 60 Pa (about 75 mTorr to about 450 mTorr) to ensure sufficient etching rate and mask selectivity. Further, for the sufficient etching rate and mask selectivity, it is preferable that the high frequency power supply 15 has a high frequency of about 40 MHz or higher and a high frequency power of about 0.5 kW to about 2.0 kw.

Preferably, the intensity of the magnetic field formed by the dipole ring magnet 24 is between about 10000 μT and about 30000 μT. Moreover, a temperature of the wafer W is preferably regulated between about −15° C. and about 30° C. to control the etching profile, i.e., the anisotropy.

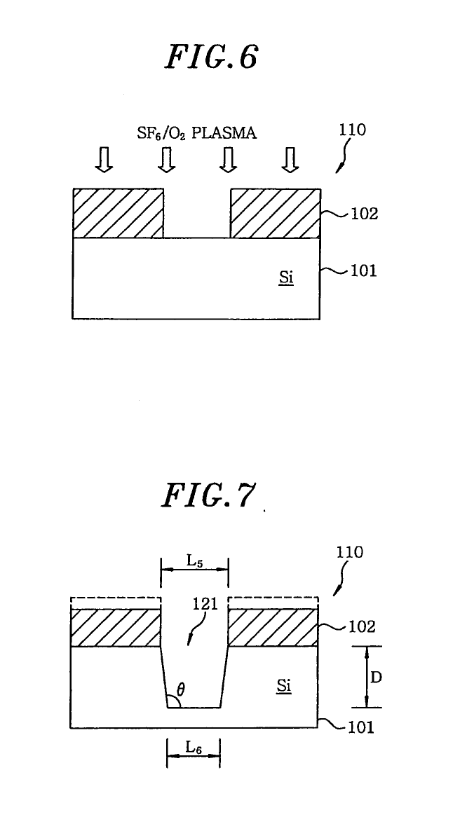

FIGS. 6 and 7 illustrate schematic cross sectional views of a vicinity of a surface of a target object 110 such as a wafer W or the like to explain a plasma etching method using the plasma etching apparatus 100 of the present invention.

As illustrated in FIG. 6, the target object 110 has on a silicon substrate 101 a resist 102 formed in a predetermined pattern. Further, an antireflection film (not illustrated) may be provided right under the resist 102. The plasma etching apparatus 100 performs a silicon etching on the target object 110 by applying the plasma of the processing gas based on the pattern of the resist 102 as a mask. As for the processing gas, it is possible to use a gas mixture of, e.g., SF₆ and O₂. The etching conditions are the same as those described in the above.

As a result of the silicon etching, a hole 121 corresponding to the pattern of the resist 102 is formed on the silicon substrate 101 with a specific depth D, as illustrated in FIG. 7. A sidewall of the hole 121 is inclined such that a diameter L₆ at its bottom edge is smaller than a diameter L₅ at its top edge. In other words, the hole 121 has a tapered cross sectional shape. In this case, an angle formed by the sidewall of the hole 121 and a horizontal direction (hereinafter, referred to as “sidewall angle”) is preferably between, e.g., about 83° and about 87°.

As described above, when the silicon substrate 101 is etched while using the resist 102 as a mask by the plasma etching apparatus 100 provided with the shower head 20 having the gas introducing openings 22 inclusively disposed near the center of the bottom surface 20b thereof and also having the ring-shaped protrusion 40, it is possible to obtain the intra-wafer uniformity of the etching rate and control the etching profile. Accordingly, the etching hole can be formed to have a uniform depth and a specific sidewall angle on the surface of the wafer W.

Although the present invention will be described in detail with experimental examples, test examples and comparative examples, the present invention is not limited thereto. A wafer W having a diameter of 8 inch (200 mm) was used in the following examples.

### Experimental Example 1

A plasma etching process was performed on the target object 110 having the structure of FIG. 6 by using the shower head 20 having the ring-shaped protrusion 40 of two sizes, A and B to be described below, thereby forming the hole 121 on the silicon substrate 101. A distance G (gap) between the upper and the lower electrode was set to be 22 mm, 27 mm and 32 mm. As for the shower head 20, one having an alumite treated surface was used.

Ring-shaped protrusion A:

Protruding amount H=15 mm

Outer diameter L₁=260 mm

Inner diameter L₂=240 mm

Width [(L₁−L₂)×½]=10 mm

Ring-shaped protrusion B:

Protruding amount H=21 mm

Outer diameter L₁=270 mm

Inner diameter L₂=240 mm

Width [(L₁−L₂)×½]=15 mm

The etching was performed under following conditions:

Resist: film thickness=7 μm

Processing gas: SF₆/O₂=170/50 mL/min (sccm)

Pressure=37.3 Pa (280 mTorr)

RF frequency (high frequency power supply 15)=40 MHz

RF power=840 W (2.68 W/cm²)

Magnetic field=17000 μT (170 G)

Backing pressure (center portion/edge portion)=1333/4000 Pa (10/30 Torr; He gas)

Temperature (lower electrode/upper electrode/chamber sidewall)=0° C./40° C./400° C.

Etching duration=4 minutes and 11 seconds

The cross sectional shape (etching profile) of the hole 121 formed by the plasma etching performed under the aforementioned conditions was evaluated in terms of the intra-wafer uniformity. A result thereof will be shown in Table 1. In controlling the etching profile in a tapered shape, a good controllability is indicated as “o”, whereas a poor controllability is indicated as “x”.

TABLE 1

| Ring-shaped | Gap (mm) | | |
|---|---|---|---|
| Protrusions | 22 | 27 | 32 |
| A | X | — | — |
| B | — | ◯ | — |
| C | — | — | ◯ |

As can be seen from Table 1, the poor controllability of the etching profile was obtained when using the ring-shaped protrusion A having a small protruding amount H of 15 mm even with the shortest gap G of 22 mm. That is, the protruding amount H needed to be greater than at least 15 mm to obtain the good controllability of the etching profile.

### Experimental Example 2

Under the same conditions as those of the experimental example 1, a plasma etching process was performed on the target object 110 having the structure of FIG. 6 by using the shower head 20 having 49 gas inlet openings 22 inclusively in an area S of about 108.7 mm² in the central portion of the bottom surface 20b thereof while setting a distance (gap) G between the upper and the lower electrode at about 22 mm, 27 mm, 32 mm or 33 mm, thereby forming the hole 121 on the silicon substrate 101. Further, the etching depth of the hole 121 was evaluated in terms of the intra-wafer uniformity. A result thereof will be shown in Table 2. The good intra-surface uniformity of the etching depth is indicated as “o”, whereas the poor intra-surface uniformity thereof is indicated as “x”.

TABLE 2

| Ring-shaped | Gap (mm) | | |
|---|---|---|---|
| Protrusions | 22 | 27 | 32 |
| A | ◯ | — | — |
| B | ◯ | — | — |
| B | — | ◯ | — |
| B | — | — | X |

As described in Table 2, in case of the shower head 20 having 49 gas inlet openings 22 inclusively in the area S of about 108.7 mm², the good intra-uniformity of the etching depth was obtained when setting the gap G at about 27 mm to about 32 mm in both of the ring-shaped protrusions A and B. However, the poor intra-wafer uniformity of the etching depth was obtained when setting the gap G at about 33 mm even by using the ring-shaped protrusion B having a protruding amount H of about 21 mm. Thus, a relationship between the protruding amount H of the ring-shaped protrusion 40 and the gap G needed to be considered to obtain the intra-wafer uniformity of the etching depth.

### Experimental Example 3

Under the same conditions as those of the experimental example 1, a plasma etching process was performed on the target object 110 having the structure of FIG. 6 by using the shower head 20 having a Y₂O₃ thermally sprayed coating surface, thereby forming the hole 121 on the silicon substrate 101. At this time, a size of the area S containing all of the gas introducing openings inclusively in the central portion of the bottom surface 20b and the number of the gas introducing openings 22 disposed therein were varied, as illustrated in Table 3. In this experiment, the distance (gap) G between the upper and the lower electrode was set to be 37 mm, and the ring-shaped protrusion 40 was not provided. Further, the etching depth of the hole 121 was evaluated in terms of the intra-wafer uniformity. A result thereof will be shown in Table 3. The good intra-wafer uniformity of the etching depth is indicated as “o”, whereas the poor intra-wafer uniformity thereof is indicated as “x”.

TABLE 3

| Number of | Gas introducing | | |
|---|---|---|---|
| Gas | opening Size of Area S | | |
| introducing | 61.7 mm × | 96.96 mm × | 120.5 mm × |
| openings | 61.7 mm | 96.96 mm | 120.5 mm |
| 25 | ◯ | — | — |
| 37 | — | ◯ | — |
| 81 | — | — | X |

As can be seen from Table 3, the good intra-wafer uniformity of the etching depth was achieved for the wafer W having a diameter of 200 mm when using the shower head 20 having 25 gas inlet openings 22 in an area S of about 61.7 mm² and the shower head 20 having 37 gas inlet openings 22 in an area S of about 99.96 mm². However, the poor intra-wafer uniformity of the etching depth was obtained when using the shower head 20 having 81 gas inlet openings 22 in an area S of about 120.5 mm².

From the above, it was clear that the arrangement and the number of gas introducing openings 22 need to be properly selected in order to achieve the good intra-wafer uniformity of the etching depth.

Based on the above experimental data, comparative examples 1 to 3 and a test example 1 were executed.

### Comparative Example 1

A plasma etching process was performed under following conditions on the target object 110 having the structure of FIG. 6 by using the conventional shower head having 153 gas introducing openings 22 arranged in an area of about 210 mm² without providing the ring-shaped protrusion 40, thereby forming the hole 121 on the silicon substrate 101.

The etching conditions were as follows:

Resist: film thickness=7 μm

Processing gas: SF₆/O₂=170/50 mL/min(sccm)

Pressure=37.3 Pa (280 mTorr)

RF frequency (high frequency power supply 15)=40 MHz

RF power=840 W (2.68 W/cm²)

Magnetic field=17000 μT (170 G)

Gap=37 mm

Backing pressure (center portion/edge portion)=1333/4000 Pa (10/30 Torr; He gas)

Temperature (lower electrode/upper electrode/chamber sidewall)=0° C./40° C./400° C.

Etching duration=4 minutes and 11 seconds

### Comparative Example 2

A plasma etching process was performed under following conditions on the target object 110 having the structure of FIG. 6 by using a shower plate provided with 153 gas introducing openings 22 inclusively arranged in an area of about 210 mm² and a ring-shaped protrusion 40 having a protruding amount H of about 21 mm, an outer diameter L₁ of about 270 mm, an inner diameter L₂ of about 240 mm and a width of about 15 mm [(L₁−L₂]×½), thereby forming the hole 121 on the silicon substrate 101.

The etching conditions were as follows:

Resist: film thickness=7 μm

Processing gas: SF₆/O₂=170/50 mL/min(sccm)

Pressure=37.3 Pa (280 mTorr)

RF frequency (high frequency power supply 15)=40 MHz

RF power=700 W (2.23 W/cm²)

Magnetic field=17000 μT (170 G)

Gap=37 mm

Backing pressure (center portion/edge portion)=1333/4000 Pa (10/30 Torr; He gas)

Temperature (lower electrode/upper electrode/chamber sidewall)=0° C./40° C./400° C.

Etching duration=4 minutes and 11 seconds

### Comparative Example 3

A plasma etching process was performed under following conditions on the target object 110 having the structure of FIG. 6 by using a shower plate having 25 gas introducing openings 22 inclusively arranged in an area of about 61.7 mm² in the central portion of the bottom surface thereof without providing the ring-shaped protrusion 40, thereby forming the hole 121 on the silicon substrate 101.

The etching conditions were as follows:

Resist: film thickness=7 μm

Processing gas: SF₆/O₂=170/50 mL/min(sccm)

Pressure=37.3 Pa (280 mTorr)

RF frequency (high frequency power supply 15)=40 MHz

RF power=840 W (2.68 W/cm²)

Magnetic field=17000 μT (170 G)

Gap=37 mm

Backing pressure (center portion/edge portion)=1333/4000 Pa (10/30 Torr; He gas)

Temperature (lower electrode/upper electrode/chamber sidewall)=0° C./40° C./400° C.

Etching duration=4 minutes and 11 seconds

### Test Example 1

A plasma etching process was performed under following conditions on the target object 110 having the structure of FIG. 6 by using a shower plate provided with 49 gas introducing openings 22 inclusively disposed in an area of about 108.7 mm² and a ring-shaped protrusion 40 having a protruding amount H of about 21 mm, an outer diameter L₁ of about 70 mm, an inner diameter L₂ of about 240 mm and a width of about 15 mm [(L₁−L₂]×½), thereby forming the hole 121 on the silicon substrate 101.

The etching conditions were as follows:

Resist: film thickness=7 μm

Processing gas: SF₆/O₂=170/50 mL/min (sccm)

Pressure=37.3 Pa (280 mTorr)

RF frequency (high frequency power supply 15)=40 MHz

RF power=500 W (1.59 W/cm²)

Magnetic field=17000 μT (170 G)

Gap=32 mm

Backing pressure (center portion/edge portion)=1333/4000 Pa (10/30 Torr; He gas)

Temperature (lower electrode/upper electrode/chamber sidewall)=0° C./40° C./400° C.

Etching duration=4 minutes and 30 seconds

After performing the plasma etching of the comparative examples 1 to 3 and the test example 1, the etching depth and the etching profile (sidewall angle) of the hole 121 were measured at multiple points in the surface of the wafer W based on images captured by a transmission type electron microscope, the measuring points including a center, an edge (50 mm), an edge (30 mm), an edge (20 mm) and an edge (10 mm) in the surface of the wafer W. The edge (50 mm) is located 50 mm away from a peripheral end of the wafer toward the center thereof. In the same manner, the edge (30 mm), the edge (20 mm) and the edge (10 mm) are respectively located 30 mm, 20 mm and 10 mm away from the peripheral end of the wafer toward the center thereof. The results of the comparative example 1 to 3 and the test example 1 are shown in Table 4.

TABLE 4

| | | | Edge | Edge | Edge | Edge | Uniformity |
|---|---|---|---|---|---|---|---|
| | | Center | 50 mm | 30 mm | 20 mm | 10 mm | (%) |
| Comparative | Etching | 111.0 | 101.9 | — | — | 88.7 | 11.1 |
| Example 1 | Depth (μm) | | | | | | |
| | Sidewall | 87.9 | 89.0 | — | — | 89.1 | 0.7 |
| | Angle (°) | | | | | | |
| Comparative | Etching | 129.0 | 121.3 | 116.0 | 110.0 | 112.7 | 8.1 |
| Example 1 | Depth (μm) | | | | | | |
| | Sidewall | 85.5 | 85.7 | — | — | 86.4 | 0.6 |
| | Angle (°) | | | | | | |
| Comparative | Etching | 90.0 | 91.8 | 89.2 | 86.4 | 82.8 | 5.1 |
| Example 1 | Depth (μm) | | | | | | |
| | Sidewall | 88.3 | 88.6 | — | — | 90.0 | 1.0 |
| | Angle (°) | | | | | | |
| Experimental | Etching | 105.0 | 111.3 | 108.2 | 105.5 | 105.0 | 3.0 |
| Example 1 | Depth (μm) | | | | | | |
| | Sidewall | 83.0 | 84.9 | — | — | 83.8 | 1.1 |
| | Angle (°) | | | | | | |

As illustrated in Table 4, the intra-uniformity of the etching depth (the depth of the hole 121) was poor when performing, without providing the ring-shaped protrusion 40, the plasma etching of the comparative example 1 using the conventional shower head having a large area for arranging the gas introducing openings 22. At this time, a sidewall angle of the hole 121 especially in the edge portion of the wafer W was measured to be substantially 90° C., which meant that a tapered cross sectional shape was not obtained.

The result of the plasma etching of the comparative example 2 using the shower head provided with a large area for arranging the gas introducing openings 22 such as the conventional shower head and also provided with the ring-shaped protrusion 40 showed an improvement in the sidewall angle of the hole 121 compared with that of the comparative example 1. However, the intra-wafer uniformity of the etching depth (the depth of the hole 121) was still poor despite the improvement in the sidewall angle.

The result of the plasma etching of the comparative example 3 using the shower head provided with only a small area for arranging the gas introducing openings 22 without the ring-shaped protrusion 40 showed an improvement in the intra-wafer uniformity of the etching depth (the depth of the hole 121) compared with those of the comparative examples 1 and 2. However, the sidewall angle of the hole 121 was substantially 90° C. as in the comparative example 1, which meant that a tapered cross sectional shape was not obtained.

The plasma etching of the test example 1 using the shower plate having the ring-shaped protrusion 40 and the gas introducing openings 22 inclusively arranged in the central portion of the bottom surface thereof showed an improvement in the intra-wafer uniformity of the etching depth (the depth of the hole 121) compared with those of the comparative examples 1 to 3. Further, a sidewall angle of the hole 121 was between about 83° C. and about 85° C., which meant that a tapered cross sectional shape was obtained in an entire surface of the wafer.

The comparison between the comparative example 1 and the comparative example 2 showed that the hole 121 having a tapered cross sectional shape and an inclined sidewall angle was obtained when using the shower plate having the ring-shaped protrusion 40.

Moreover, the comparison between the comparative example 1 and the comparative example 3 showed that the intra-wafer uniformity of the etching depth was improved when using the shower plate having the gas introducing openings 22 inclusively provided in the central portion of the bottom surface thereof.

However, as can be seen from the comparison between the comparative examples 2 and 3 and the test example 1, the test example 1 using the shower plate having the ring-shaped protrusion 40 and the gas introducing openings 22 inclusively disposed in the central portion showed improvements in the intra-wafer uniformity of the etching depth and the controllability of the sidewall angle of the hole 121 compared with those of the comparative examples 2 and 3. That is, the result of the test example 1 did not show an aggregated result of the comparative examples 2 and 3 but an improvement in both the intra-wafer uniformity of the etching depth and the controllability of the etching.

The present invention can be modified without being limited to the aforementioned embodiments. For example, although the dipole ring magnet is used as a magnetic field forming unit of the magnetron RIE plasma etching apparatus in the aforementioned embodiments, the magnetic field forming unit is not limited thereto and, also, it is unnecessary to form a magnetic field. As long as a plasma of the gas species of the present invention can be generated, there can be used various plasma etching apparatuses such as a capacitively coupled plasma etching apparatus, an inductively coupled plasma etching apparatus and the like.

The present invention can be appropriately used for manufacturing various semiconductor devices such as a transistor and the like.

While the invention has been shown and described with respect to the embodiments, it will be understood by those skilled in the art that various changes and modification may be made without departing from the scope of the invention as defined in the following claims.

What is claimed is:

1. A plasma etching method, by using a plasma etching apparatus including an evacuable processing chamber for performing a plasma etching process on a target object, a mounting table for mounting thereon the target object in the processing chamber, a shower head facing the mounting table, for introducing a processing gas for generating a plasma to the processing chamber, a ring-shaped protrusion protruded from a bottom surface of the shower head toward the mounting table, and a plurality of gas introducing openings inclusively arranged in an area smaller than the target object in an inner central portion of the ring-shaped protrusion on the bottom surface of the shower head, the plasma etching method comprising:
performing a plasma etching process on the target object having an etching target layer mainly made of silicon and a pre-patterned resist layer formed above the etching target layer by applying a plasma generated from a processing gas containing SF₆ and O₂ to the etching target layer while using the resist layer as a mask.

2. The plasma etching method of claim 1, wherein the etching target layer is a silicon substrate or a silicon layer.

3. A computer-executable control program, which controls, when executed, the plasma etching apparatus such that the plasma etching method described in claim 1 is performed.

4. A computer readable storage medium that stores therein a computer-executable control program, wherein the control program controls the plasma etching apparatus such that the plasma etching method described in claim 1 is performed.

5. The plasma etching method of claim 1, wherein an etch hole formed in the etching target layer has a tapered shape, in which a width at an opening of the etching hole is greater than that at a bottom thereof.
